(19) United States
(12) Patent Application Publication
(10) Pub. No.: US 2013/0029434 A1
(43) Pub. Date: Jan. 31, 2013

(54) METHOD OF FABRICATING SEMICONDUCTOR DEVICE INCLUDING CALIBRATING PROCESS CONDITIONS AND CONFIGURATIONS BY MONITORING PROCESSES

(71) Applicant: Jang-Sun KIM, Hwaseong-si (KR)

(72) Inventor: Jang-Sun KIM, Hwaseong-si (KR)

(73) Assignee: Samsung Electronics Co., Ltd., Suwon-si (KR)

(21) Appl. No.: 13/555,375

(22) Filed: Jul. 23, 2012

(30) Foreign Application Priority Data
Jul. 29, 2011 (KR) 10-2011-0076152

(51) Int. Cl. H01L 21/66

(52) U.S. Cl. 438/7; 257/E21.53

(57) ABSTRACT

A method of fabricating a semiconductor device includes performing a first period of operation and a second period of operation at first equipment and second equipment. The first period of operation includes performing a first patterning process at each of the first equipment and the second equipment, generating first inspection data of the first equipment and first inspection data of the second equipment, generating first differential data of the second equipment including differentials of the first inspection data of the first equipment and the first inspection data of the second equipment, and calibrating a configuration of the second equipment with reference to the first differential data of the second equipment.

### CROSS-REFERENCE TO RELATED APPLICATIONS

This application claims priority under 35 U.S.C. §119 to Korean Patent Application No. 10-2011-0076152 filed on Jul. 29, 2011, the disclosure of which is hereby incorporated by reference in its entirety.

### BACKGROUND

1. Field

The general inventive concept relates to a method of calibrating process conditions and/or configurations of equipment by monitoring various processes during the processing of a workpiece.

2. Description of the Related Art

Semiconductors are processed and manufactured through various processes of wafers. One process is performed using a plurality of the same equipment, rather than one apparatus. When a plurality of equipment is being operated, the process results of each of the respective equipment used are important. Accordingly, it is necessary to monitor the processes of the respective equipment at each stage during processing to calibrate process conditions and/or configurations of the equipment.

### SUMMARY

Exemplary embodiments of the inventive concept provide a method of monitoring a process and/or equipment.

Additional features and utilities of the present general inventive concept will be set forth in part in the description which follows and, in part, will be obvious from the description, and/or may be learned by practice of the general inventive concept.

Exemplary embodiments of the inventive concept also provide a method of calibrating a process and/or equipment.

Exemplary embodiments of the inventive concept also provide a method of fabricating a semiconductor device.

The technical objectives of the inventive concept are not limited to the above disclosure; other objectives may become apparent to those of ordinary skill in the art based on the following descriptions.

In accordance with feature of the present general inventive concept, a method of fabricating a semiconductor device includes performing a first period of operation and a second period of operation at first equipment and second equipment. The first period of operation includes: performing a first patterning process at each of the first equipment and the second equipment; generating first inspection data of the first equipment, and first inspection data of the second equipment; generating first differential data of the second equipment including differentials of the first inspection data of the first equipment and the first inspection data of the second equipment; and calibrating a configuration of the second equipment with reference to the first differential data of the second equipment. The second period of operation includes: performing a second patterning process at the first equipment and the second equipment; generating second inspection data of the first equipment, and second inspection data of the second equipment; generating first differential data of the first equipment including differentials of the first inspection data of the first equipment and the second inspection data of the first equipment; and calibrating a configuration of the first equipment with reference to the first differential data of the first equipment.

In exemplary embodiments, the patterning process may include forming a photoresist pattern.

In another exemplary embodiment, the first and second equipment may include photolithography equipment.

In still another exemplary embodiment, the inspection data may include geometric positional correlations of patterns formed by the patterning processes. In yet another exemplary embodiment, the second period of operation may further include generating second differential data of the second equipment including differentials of the second inspection data of the first equipment and the second inspection data of the second equipment; and calibrating the configuration of the second equipment with reference to the second differential data of the second equipment.

In yet another exemplary embodiment, the method may further include performing a third period of operation at the first equipment and the second equipment. The third period of operation may include performing a third patterning process at the first equipment; generating third inspection data of the first equipment; generating second differential data of the first equipment including differentials of the second inspection data of the first equipment and the third inspection data of the first equipment; and calibrating the configuration of the first equipment with reference to the first differential data of the first equipment.

In yet another exemplary embodiment, the third period of operation may further include performing a third patterning process at the second equipment; generating third inspection data of the second equipment; generating third differential data of the second equipment including differentials of the third inspection data of the first equipment and the third inspection data of the second equipment; and calibrating the configuration of the second equipment with reference to the third differential data of the second equipment.

In yet another exemplary embodiment, the method may further include performing a fourth period of operation at the first equipment and the second equipment. The fourth period of operation may include performing a fourth patterning process at the second equipment; generating fourth inspection data of the second equipment; generating fourth differential data of the second equipment including differentials of the third inspection data of the second equipment and the fourth inspection data of the second equipment; and calibrating the configuration of the second equipment with reference to the fourth differential data of the second equipment.

In accordance with another feature of the inventive concept, a method of fabricating a semiconductor device includes performing a first period of operation. The first period of operation includes: performing a first patterning process at each of first, second and third equipment; generating first inspection data of the first equipment, first inspection data of the second equipment, and first inspection data of the third equipment; generating first differential data of the second equipment including differentials of the first inspection data of the first equipment and the first inspection data of the second equipment; generating first differential data of the third equipment including differentials of the first inspection data of the first equipment and the first inspection data of the third equipment; calibrating a configuration of the first equipment with reference to first differential data of the first equipment; and calibrating a configuration of the second equipment with reference to first differential data of the second equipment. In some exemplary embodiments, the method may further include performing a second period of operation. The second period of operation may include performing a second patterning process at the first equipment; generating second inspection data of the first equipment; generating first differential data of the first equipment including differentials of the first inspection data of the first equipment and the second inspection data of the first equipment; and calibrating a configuration of the first equipment with reference to the first differential data of the first equipment.

In accordance with another feature of the inventive concept, a method of fabricating a semiconductor device includes performing a first process of a first period at a first equipment, wherein the first process of the first period includes forming first patterns on first to third ones of first wafers, performing a second process of the first period at a second equipment, wherein the second process of the first period includes forming a second pattern on a second wafer and generating a first differential data of the second equipment by comparing inspection results of the first pattern on the second one of the first wafer and inspection results of the second pattern on the second wafer; and performing a third process of the first period at a third equipment, wherein the third process of the first period comprises forming a third pattern on a third wafer and generating a first differential data of the third equipment by comparing inspection result of the first pattern on the third one of the first wafer and inspection results of the third pattern on the third wafer.

In exemplary embodiments, the method further includes calibrating a configuration of the second equipment with reference to the first differential data of the second equipment, and calibrating a configuration of the third equipment with reference to the first differential data of the third equipment.

In another exemplary embodiment, the method further includes performing a first process of a second period at the first equipment, wherein the first process of the second period includes forming fourth patterns on first to third ones of fourth wafers, and generating a first differential data of the first equipment by comparing inspection results of the first pattern on the first one of the first wafers and the fourth pattern on the first one of the fourth wafers, performing a second process of the second period at the second equipment, wherein the second process of the second period includes forming a fifth pattern on a fifth wafer, and generating a second differential data of the second equipment by comparing inspection results of the fourth pattern on the second one of the fourth wafers and inspection results of the fifth pattern on the fifth wafer, and performing a third process of the second period at the third equipment, wherein the third process of the second period includes forming a sixth pattern on a sixth wafer, and generating a second differential data of the third equipment by comparing inspection results of the fourth pattern on the third one of the fourth wafers and inspection results of the sixth pattern on the sixth wafer.

In still another exemplary embodiment, the method further includes calibrating a configuration of the first equipment with reference to the first differential data of the first equipment, calibrating a configuration of the second equipment with reference to the second differential data of the second equipment, and calibrating a configuration of the third equipment with reference to the second differential data of the third equipment.

In yet another exemplary embodiment, the method further includes performing a first process of a third period at the first equipment, wherein the first process of the third period includes forming seventh patterns on first to third ones of seventh wafers and generating a second differential data of the first equipment by comparing inspection results of the fourth pattern on the first one of the fourth wafers and the seventh pattern on the first one of the seventh wafers, performing a second process of the third period at the second equipment, wherein the second process of the third period includes forming an eighth pattern on a eighth wafer, and generating a third differential data of the second equipment by comparing inspection results of the seventh pattern on the second one of the seventh wafers and inspection results of the eighth pattern on the eighth wafer, and performing a third process of the third period at the third equipment, wherein the third process of the third period includes forming a ninth pattern on a ninth wafer, and generating a third differential data of the third equipment by comparing inspection results of the seventh pattern on the third one of the seventh wafers and inspection results of the ninth pattern on the ninth wafer.

In yet another exemplary embodiment, the method further includes calibrating a configuration of the first equipment with reference to the second differential data of the first equipment, calibrating a configuration of the second equipment with reference to the third differential data of the second equipment, and calibrating a configuration of the third equipment with reference to the third differential data of the third equipment.

In yet another exemplary embodiment, the method further includes performing a first process of a fourth period at the second equipment, wherein the first process of the fourth period comprises forming tenth patterns on first and second ones of tenth wafers and generating a fourth differential data of the second equipment by comparing inspection results of the eighth pattern on the eighth wafer and inspection results of the tenth pattern on the first one of the tenth wafers, and performing a second process of the fourth period at the third equipment, wherein the second process of the fourth period comprises forming an eleventh pattern on an eleventh wafer, and generating a fourth differential data of the third equipment by comparing inspection results of the tenth pattern on the second one of the tenth wafers and inspection results of the eleventh pattern on the eleventh wafer.

In yet another exemplary embodiment, the method further includes stopping operation of the first equipment in the fourth period.

In yet another exemplary embodiment, the patterns have the same features.

In another exemplary embodiment, the second period of operation may further include performing the second patterning process at the second equipment; generating second inspection data of the second equipment; generating second differential data of the second equipment including differentials of the second inspection data of the first equipment and the second inspection data of the second equipment; and calibrating the configuration of the second equipment with reference to the second differential data of the second equipment.

In still another exemplary embodiment, the second period of operation may include performing the second patterning process at the third equipment; generating second inspection data of the third equipment; generating second differential data of the third equipment including differentials of the second inspection data of the first equipment and the second inspection data of the third equipment; and calibrating the configuration of the third equipment with reference to the second differential data of the third equipment.

In yet another exemplary embodiment, the method may further include performing a third period of operation. The third period of operation may include performing a third patterning process at the second equipment; generating third inspection data of the second equipment; generating third differential data of the second equipment including differentials of the second inspection data of the second equipment and the third inspection data of the second equipment; and calibrating the configuration of the second equipment with reference to the third differential data of the second equipment.

In yet another exemplary embodiment, the third period of operation may further include performing the third patterning process at the third equipment; generating third inspection data of the third equipment; generating third differential data of the third equipment including differentials of the third inspection data of the second equipment and the third inspection data of the third equipment; and calibrating the configuration of the third equipment with reference to the third differential data of the third equipment.

In another exemplary embodiment, the method of fabricating, at first equipment and second equipment, a semiconductor device, includes performing a first period of operation to provide a first differential data including differentials of process and inspection data of the second equipment using first process and inspection data from the first and second equipment; calibrating a configuration of the second equipment using the first differential data of the process and inspection data of the first and the second equipment; performing a second period of operation to provide a second differential data including differentials of process and inspection data of the first equipment using first process and inspection data from the first equipment and second process and inspection data from the first equipment; and calibrating a configuration of the first equipment using the second differential data of the process and inspection data from the first equipment and the second process and inspection data from the first equipment.

In yet another exemplary embodiment, the inspection data may include geometric inspection results of photoresist patterns formed by the patterning processes.

Specific matters of other exemplary embodiments are included in the detailed description and drawings.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a block diagram illustrating a communication network of equipment in accordance with exemplary embodiments of the present general inventive concept;

FIGS. 2A and 2B are flowcharts illustrating a method of fabricating a semiconductor device in accordance with an exemplary embodiment of the present general inventive concept;

FIGS. 3A to 3C are flowcharts illustrating a method of fabricating a semiconductor device in accordance with a second exemplary embodiment of the present general inventive concept;

FIGS. 4A to 4C are flowcharts illustrating a method of fabricating a semiconductor device in accordance with a third exemplary embodiment of the present general inventive concept;

FIGS. 5A and 5B are flowcharts illustrating a method of fabricating a semiconductor device in accordance with a fourth exemplary embodiment of the present general inventive concept;

FIGS. 6A and 6B are flowcharts illustrating a method of fabricating a semiconductor device in accordance with a fifth exemplary embodiment of the present general inventive concept;

FIGS. 7A and 7B are flowcharts illustrating a method of fabricating a semiconductor device in accordance with a sixth exemplary embodiment of the present general inventive concept;

FIGS. 8A and 8B are flowcharts illustrating a method of fabricating a semiconductor device in accordance with a seventh exemplary embodiment of the present general inventive concept;

FIGS. 9A and 9B are flowcharts illustrating a method of fabricating a semiconductor device in accordance with an eighth exemplary embodiment of the present general inventive concept; and

FIGS. 10A to 12 are views illustrating exemplary embodiments in accordance with the present general inventive concept, to which methods of fabricating semiconductor devices are applied.

FIG. 13 is a flowchart illustrating a method of fabricating a semiconductor device in accordance with another exemplary embodiment of the present general inventive concept.

### DETAILED DESCRIPTION OF THE EMBODIMENTS

Reference will now be made in detail to exemplary embodiments of the present general inventive concept, examples of which are illustrated in the accompanying drawings, wherein like reference numerals refer to the like elements throughout. The exemplary embodiments are described below in order to explain the present general inventive concept while referring to the figures.

It will be understood that when an element and/or layer is referred to as being “on,” “connected to” and/or “coupled with” another element and/or layer, it may be directly on, connected and/or coupled with the other element and/or layer and/or intervening elements and/or layers may be present. In contrast, when an element is referred to as being “directly on,” “directly connected to” and/or “directly coupled with” another element and/or layer, there are no intervening elements and/or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer and/or section from another region, layer and/or section. Thus, a first element, component, region, layer and/or section discussed below could be termed a second element, component, region, layer and/or section without departing from the teachings of the present inventive concept.

Spatially relative terms, such as “beneath,” “below,” “lower,” “above,” “upper” and the like, may be used herein for ease of description to describe one element's and/or feature's relationship to another element(s) and/or feature(s) as illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements and/or features would then be oriented “above” the other elements and/or features. Thus, the term “below” may encompass both an orientation of above and below. The device may be otherwise oriented (rotated 90 degrees and/or at other orientations) and the spatially relative descriptors used herein interpreted accordingly.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence and/or addition of one or more other features, integers, steps, operations, elements, components, and/or groups thereof.

Exemplary embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded and/or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized and/or overly formal sense unless expressly so defined herein.

Descriptions of the specification may be variously applied as a method of monitoring a process and/or equipment, a method of controlling the same, a method of calibrating the same, and/or a method of fabricating a semiconductor device.

In the specification, the description that various differentials and relational expressions may be further calculated means that various resultant values may be obtained by artificially inputting conventional and/or new reference numerals, parameters, and/or formulae.

In the inventive concept, first to fourth processes may include a patterning process of forming a pattern. For example, the first to fourth processes may include a photolithography process including a development process. More specifically, the respective processes may include an exposure process and/or the development process. In addition, the respective processes may include the exposure process, a pre-bake process, and/or the development process. In the inventive concept, inspection data may include results of photoresist patterns that are measured. For example, the inspection data may include results that, after performing the exposure process and the development process and before performing an etching process, geometric positional relationships and/or critical dimensions (CD) of the photoresist patterns are measured.

In the inventive concept, processes of generating inspection data may include an after develop inspection (ADI) process. Accordingly, the inspection data may include geometric inspection results of the photoresist patterns. In the processes of inspecting/measuring the results where the photoresist process is performed, after performing the exposure process, the ADI process is performed at the earliest time. Accordingly, according to the inventive concept, an operation of monitoring and calibrating the photolithography processes and equipment may be performed within the quickest time. In particular, since inspection of overlay, alignment, or the like, and calibration of the processes and equipment may be relatively simply managed, the amount of time of the formation and inspection of a final pattern, and calibration of the processes and equipment may be excessively consumed.

Calibration of the configurations of the equipment in the specification and claims may be understood as calibrating the configurations of software and hardware of the equipment. The software of the equipment may include process conditions and process recipes.

“Inspection” may include “measurement” and/or “check”.

FIG. 1 is a block diagram conceptually showing a communication network of equipment in accordance with the present general inventive concept. The communication network of the equipment in accordance with the inventive concept may include a central control unit CCU, first equipment E1, second equipment E2, third equipment E3, and inspection equipment E1. The central control unit CCU may communicate with the first to third equipment E1 to E3. The central control unit CCU may collect first data from the first to third equipment E1 to E3, and compute the data to generate second data. The second data may be selectively transmitted and/or distributed to the first to third equipment E1 to E3 and/or the inspection equipment E1.

The first to third equipment E1 to E3 may perform a photolithography process. For example, the first to third equipment E1 to E3 may include exposure equipment and/or development equipment, respectively. The first equipment E1 may provide a reference to the second and third equipment E2 and E3. Accordingly, the second and third equipment E2 and E3 may be calibrated according to the reference provided by the first equipment E1.

The inspection equipment E1 may monitor process results performed by the first to third equipment E1 to E3. The inspection equipment E1 may include an optical and/or electronic monitor, a visualizer, a scanner, a camera, a comparator, and/or a ruler.

Furthermore, the communication network may further include a plurality of other equipment. For example, the communication network may further include fourth equipment different from the first to third equipment E1 to E3.

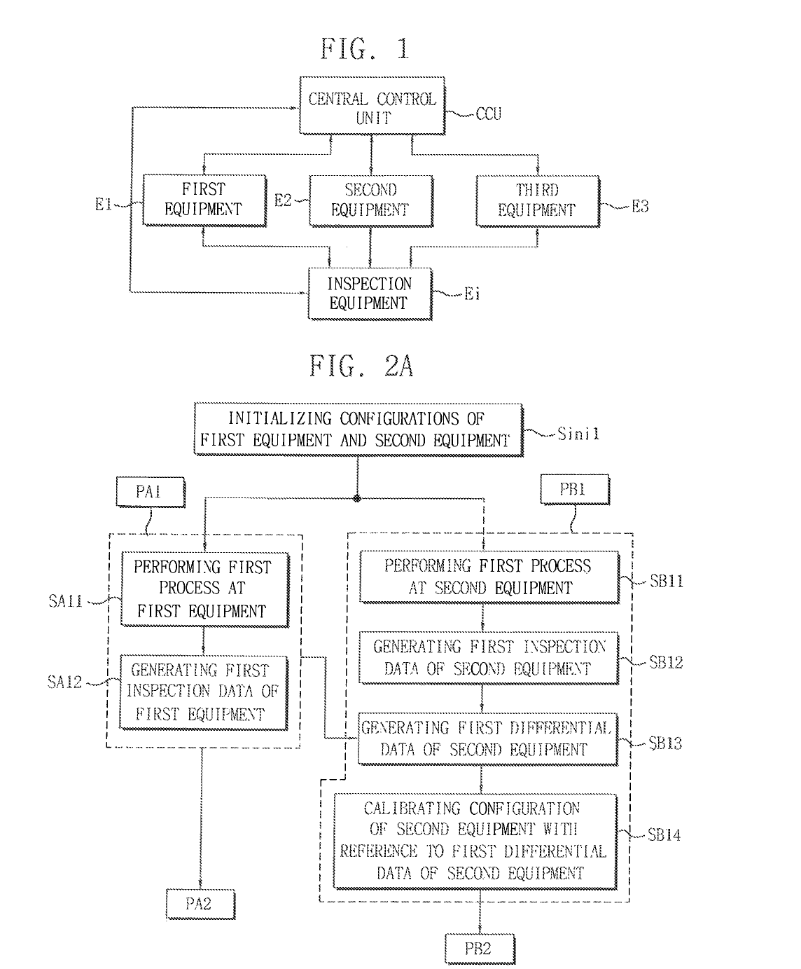

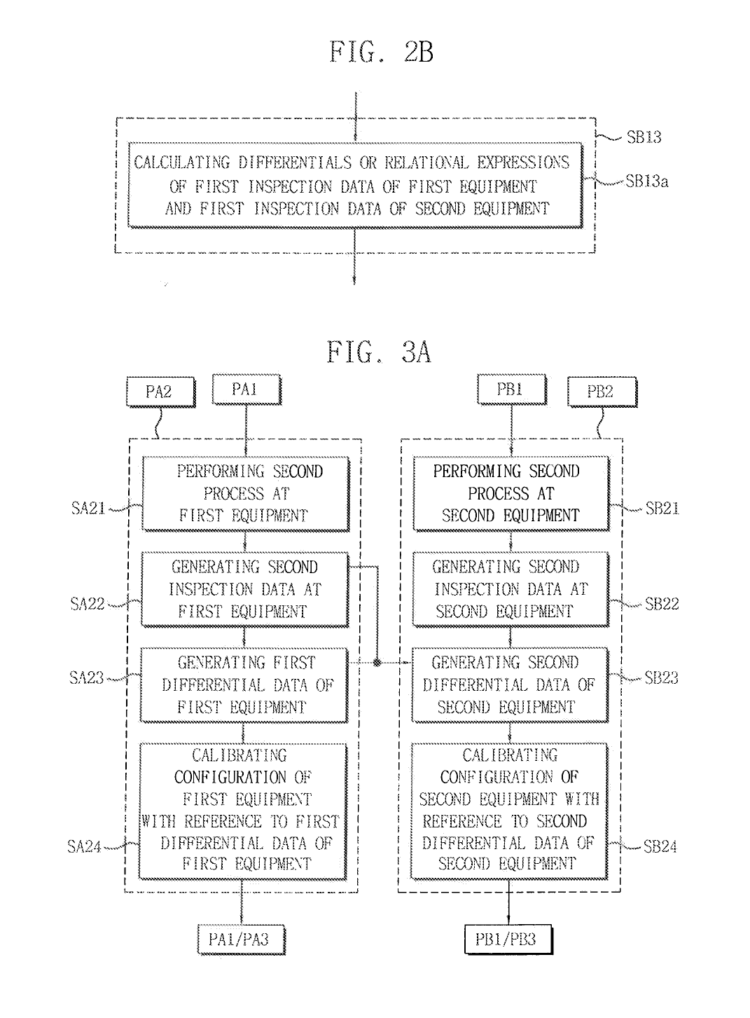

FIGS. 2A and 2B are flowcharts illustrating a method of fabricating a semiconductor device in accordance with an exemplary embodiment of the present general inventive concept.

Referring to FIG. 2A, the method of fabricating a semiconductor device in accordance with the first embodiment of the present general inventive concept may include initializing configurations of the first and second equipment (step Sini1). Initialization of the configurations of the respective equipment may include equalization of process parameters, operating conditions, and/or process recipes, and/or independent initialization thereof according to characteristics of the respective equipment. Then, the first and second equipment may perform a first period of operations PA1 and PB1, respectively.

The first period of operation PA1 of the first equipment may include performing a first process at the first equipment (step SA11), and generating first inspection data of the first equipment (step SA12). For example, the first period may be a first day.

Performing the first process at the first equipment (step SA11) may include forming first patterns on a plurality of first wafers. For example, the first process may include forming first photoresist patterns on the first wafers by performing a photolithography process.

Generating the first inspection data of the first equipment (step SA12) may include inspection results of the first process performed by the first equipment. For example, the step SA12 may include inspecting/measuring the first pattern formed on first to second ones of the first wafers. Inspecting/measuring the first pattern may include inspecting/measuring the thickness, a depth, a width, a length, a position, and/or various other numbers of the first patterns.

Generating the first inspection data of the first equipment (step SA12) may include converting the inspection results into numerical data. In addition, calculating differentials and/or relational expressions between target values and inspection results may be included. Accordingly, the first inspection data of the first equipment may selectively include differentials and/or relational expressions obtained from various numerals and target values thereof. For example, the first inspection data of the first equipment may include an inspection numeral A1.

The inspection equipment to generate the inspection numeral A1 may be installed in the first equipment. That is, generating the first inspection data of the first equipment may be performed by itself in the first equipment, not using separate inspection equipment. The first inspection data of the first equipment may be generated using the inspection equipment and/or the central control unit. Next, the second period of operation PA2 of the first equipment may be performed.

The first period of operation PB1 of the second equipment may include performing a first process at the second equipment (step SB11), generating first inspection data of the second equipment (step SB12), and generating first differential data of the second equipment (step SB13).

The first process of the second equipment may include the same process as the first process of the first equipment. For example, the first process of the second equipment may include forming a second pattern on a second wafer. The second pattern may have the same features of the first patterns.

Generating the first inspection data of the second equipment (step SB12) may include inspecting/measuring the second pattern on the second wafer. Furthermore, generating the first inspection data of the second equipment (step SB12) may include inspecting/measuring results of the first process performed by the second equipment, and calculating differentials and/or relational expressions between the target numerals and the results. For example, the first inspection data of the second equipment may include an inspection numeral B1. The first inspection data of the second equipment may also be generated using the separate inspection equipment and/or the central control unit CCU.

Referring further to FIG. 2B, generating first differential data of the second equipment (step SB13) may include calculating differentials and/or relational expressions of the first inspection data of the first equipment and the first inspection data of the second equipment (step SB13a). For example, the step (SB13) may include comparing inspection/measurement results of the first pattern formed on the second one of the first wafers and inspection/measurement results of the second pattern formed on the second wafer. When the first inspection data of the first equipment includes the inspection numeral A1 and the first inspection data of the second equipment includes the inspection numeral B1, the first differential data of the second equipment may include differentials and/or relational expressions calculated between the A1 and B1 as follows:

A1=B1−ΔB1, (Δis a differential) (1)

B1=A1+ΔB1 (2)

ΔAB1=B1−A1 (3)

Accordingly, the first differential data of the second equipment may include differentials and/or relational expressions of process results of the first and second equipment. The first differential data of the second equipment may be generated by itself and/or using the inspection equipment E1 and/or the central control unit CCU of FIG. 1.

Referring again to FIG. 2A, the first period of operation PB1 of the second equipment may further include calibrating the configuration of the second equipment with reference to the first differential data of the second equipment (step SB14). Next, the second period of operation PB2 of the second equipment may be performed. Configurations of the respective equipment must be understood as concept including all hardware and software elements.

According to the first embodiment of the inventive concept, numerically various differentials and/or relational expressions may be obtained to determine which relations are provided by the initial configuration of the first equipment and the configuration and/or results of the second equipment. Accordingly, according to the first embodiment of the inventive concept, since the configuration of the second equipment may be calibrated with reference to the initial configuration and/or the varied configuration of the first equipment, the process, the process results and environment of the equipment may be controlled and always maintained within a certain range.

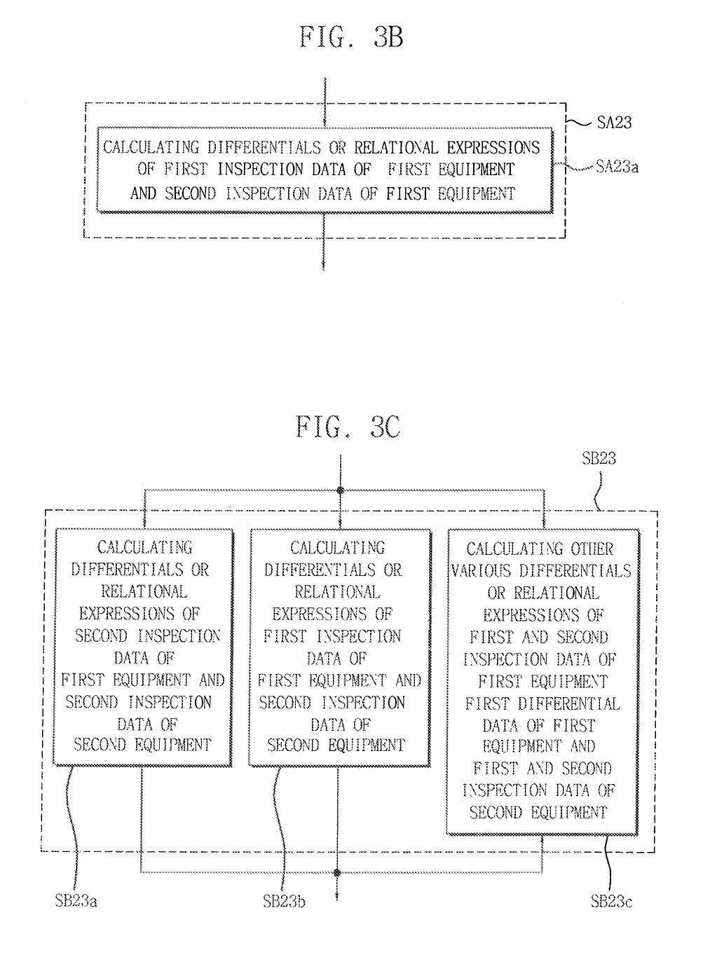

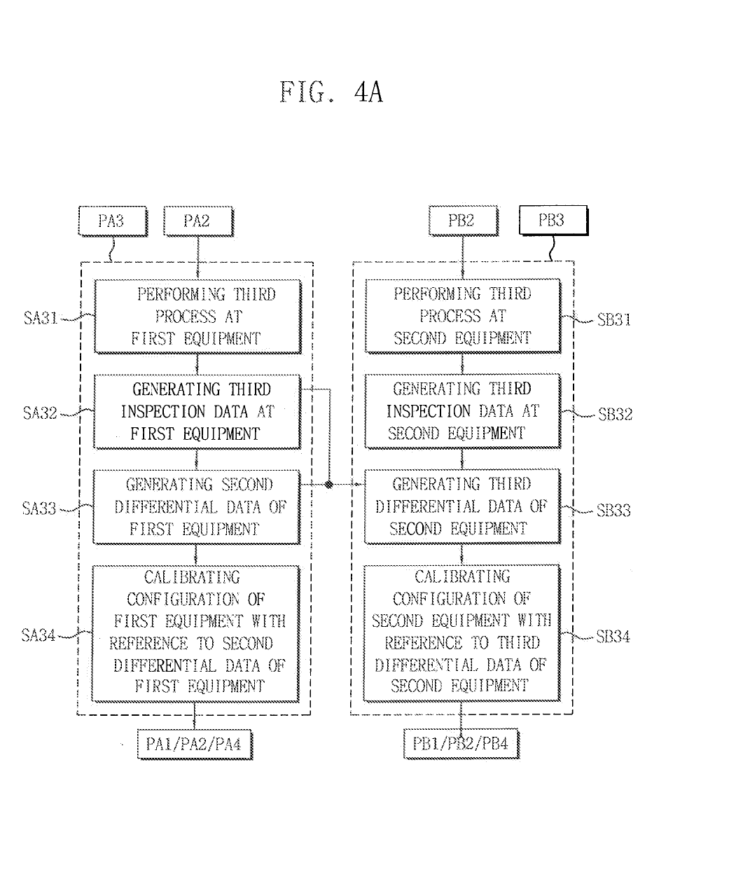

FIGS. 3A to 3C are flowcharts illustrating a method of fabricating a semiconductor device in accordance with a second exemplary embodiment of the present general inventive concept.

Referring to FIG. 3A, the method of fabricating a semiconductor device in accordance with the second exemplary embodiment of the present general inventive concept may include a monitoring method according to the first exemplary embodiment, and performing a second period of operations PA2 and PB2 at the first and second equipment, respectively. For example, the second period may be a second day.

The second period of operation PA2 of the first equipment may include performing a second process at the first equipment (step SA21), generating second inspection data of the first equipment (step SA22), and generating first differential data of the first equipment (step SA23).

The second process of the first equipment may include the same process as the first process of the first equipment. For example, the second process of the first equipment may include forming third patterns on a plurality of third wafers. The third patterns may have the same features as the first patterns.

Generating the second inspection data of the first equipment (step SA22) may include inspecting/measuring results of the second process performed by the first equipment. For example, the step (SA22) may include inspecting/measuring the third pattern formed on first to second ones of the plurality of third wafers.

Referring further to FIG. 3B, generating the first differential data of the first equipment (step SA23) may include calculating differentials and/or relational expressions of the first inspection data of the first equipment and the second inspection data of the first equipment. For example, the step (SA23) may include comparing inspection/measurement results of the first pattern formed on the first one of the first wafers and inspection/measurement results of the third pattern formed on the first one of the plurality of the third wafers. When the second inspection data of the first equipment includes the inspection numeral A2, the first differential data of the first equipment may include differentials and/or relational expressions calculated between the A1 and A2 as follows:

A1=A2−ΔA2 (4)

A2=A1+ΔA2 (5)

ΔA2=A2−A1 (6)

Referring again to FIG. 3A, the second period of operation PA2 of the first equipment may further include calibrating the configuration of the first equipment with reference to the first differential data of the first equipment (step SA24). Next, the first period of operation PA1 and/or a third period of operation PA3 of the first equipment may be performed.

Continuously referring to FIG. 3A, the second period of operation PB2 of the second equipment may include performing a second process at the second equipment (step SB21), generating second inspection data of the second equipment (step SB22), and generating second differential data of the second equipment (step SB23).

The second process of the second equipment may include the same process as the second process of the first equipment. For example, the process of the second equipment may include forming a fourth pattern on a fourth wafer. The fourth pattern may have the same features as the third patterns.

Generating the second inspection data of the second equipment (step SB22) may include inspecting/measuring results of the second process performed by the second equipment. For example, the second inspection data of the second equipment (step SB22) may include inspecting/measuring the fourth pattern formed on the fourth wafer.

Referring further to FIG. 3C, generating the second differential data of the second equipment (step SB23) may include calculating differentials and/or relational expressions of the second inspection data of the first equipment and the second inspection data of the second equipment (step SB23a), calculating differentials and/or relational expressions of the first inspection data of the first equipment and the second inspection data of the second equipment (step SB23b), and calculating other various differentials and/or relational expressions of the first and second inspection data of the first equipment, the first differential data of the first equipment, and the first and second inspection data of the second equipment (step SB23c). For example, generating the second differential data of the second equipment (step SB23) may include comparing inspection/measurement results of the third pattern formed on the second one of the third wafers and inspection/measurement results of the fourth pattern formed on the fourth wafer. When the first inspection data of the first equipment includes the inspection numeral A1, the second inspection data of the first equipment includes the inspection numeral A2, the first differential data of the first equipment includes the differential numeral ΔA1, the first inspection data of the second equipment includes the inspection numeral B1, and the second inspection data of the second equipment includes the inspection numeral B2, the second differential data of the second equipment may include various differentials and/or relational expressions calculated between the A1, A2 and B2 as follows:

ΔB2=B2−A2 (7)

ΔB2=B2−(ΔA2+A1) (8)

ΔB2+ΔA2=B2−A1 (9)

Otherwise, various differentials and/or relational expressions may be further calculated and/or included.

Referring again to FIG. 3A, calibrating the configuration of the second equipment with reference to the second differential data of the second equipment (step SB24) may be further included. Next, the first period of operation PB1 and/or a third period of operation PB3 of the second equipment may be performed.

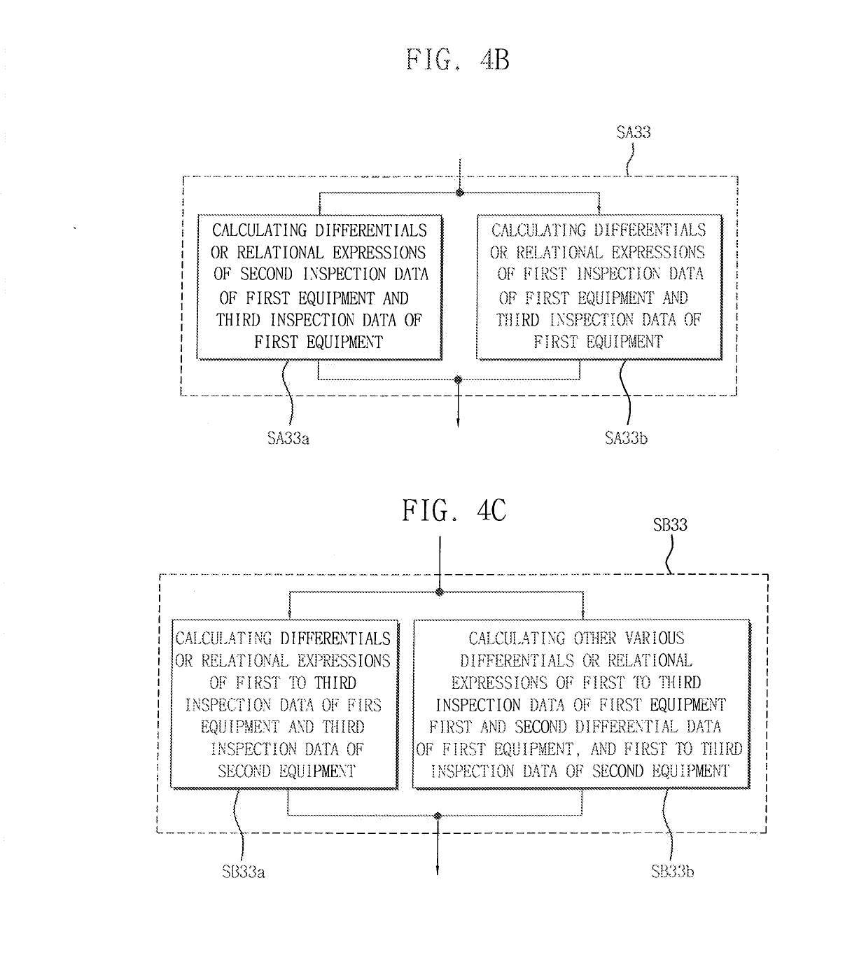

FIGS. 4A to 4C are flowcharts illustrating a method of fabricating a semiconductor device in accordance with a third exemplary embodiment of the present general inventive concept.

Referring to FIG. 4A, the method of fabricating a semiconductor device in accordance with the third embodiment of the inventive concept may include the methods of fabricating a semiconductor device in accordance with the first and second embodiments, and a third period of operations PA3 and PB3 may include performing the operations PA3 and PB3 at the first equipment and the second equipment, respectively. For example, the third period may be a third day.

The third period of operation PA3 of the first equipment may include performing a third process at the first equipment (step SA31), generating third inspection data of the first equipment (step SA32), and generating second differential data of the first equipment (step SA33).

The third process of the first equipment may include the same process as the first process and/or the second process of the first equipment. For example, the third process of the first equipment may include forming fifth patterns on a plurality of fifth wafers. The fifth patterns may have the same features as the third patterns.

Generating the third inspection data of the first equipment (step SA32) may include inspecting/measuring results of the third process performed by the first equipment. For example, the third inspection data of the first equipment (step SA32) may include inspecting/measuring the fifth pattern formed on first to second ones of the fifth wafers.

Referring further to FIG. 4B, generating the second differential data of the first equipment (step SA33) may include calculating differentials and/or relational expressions of the second inspection data of the first equipment and the third inspection data of the first equipment (step SA33a), and calculating differentials and/or relational expressions of the first inspection data of the first equipment and the third inspection data of the first equipment (step SA33b). For example, generating the second differential data of the first equipment (step SA33) may include comparing inspection/measurement results of the third pattern formed on the first one of the third wafers and inspection/measurement results of the fifth pattern formed on the first one of the fifth wafers. When the third inspection data of the first equipment includes the inspection numeral A3, the second differential data of the first equipment may include various differentials and/or relational expressions calculated between the A1, A2 and A3 as follows:

ΔA3=A3−A2 (10)

A3Δ32 A3+A2 (11)

ΔA3=A3−ΔA2−A1 (12)

ΔA3+ΔA2=A3−A1 (13)

In addition, various differentials and/or relational expressions may be further calculated and/or included.

Referring again to FIG. 4A, the third period of operation PA3 of the first equipment may further include calibrating the configuration of the first equipment with reference to the second differential data of the first equipment. Next, the first period of operation PA1, the second period of operation PA2 and/or a fourth period of operation PA4 of the first equipment may be performed.

Continuously referring to FIG. 4A, the third period of operation PB3 of the second equipment may include performing a third process at the second equipment (step SB31), generating third inspection data of the second equipment (step SB32), and generating third differential data of the second equipment (step SB33).

The third process of the second equipment may include the same process as the third process of the first equipment. For example, the third process of the second equipment may include forming a sixth pattern on a sixth wafer. The sixth pattern may have the same features as the fifth patterns.

Generating the third inspection data of the second equipment (step SB32) may include inspecting/measuring results of the third process performed by the second equipment. For example, generating the third inspection data of the second equipment (step SB32) may include inspecting/measuring the sixth pattern formed on the sixth wafer.

Referring further to FIG. 4C, generating the third differential data of the second equipment (step SB33) may include calculating differentials and/or relational expressions of the first to third inspection data of the first equipment and the third inspection data of the second equipment (step SB33a), and calculating other various differentials and/or relational expressions of the first to third inspection data of the first equipment, the first and second differential data of the first equipment, and the first to third inspection data of the second equipment (step SB33b).

For example, comparing inspection/measurement results of the fifth pattern formed on the second one of the fifth wafers and inspection/measurement results of the sixth pattern formed on the sixth wafer. When the first inspection data of the first equipment includes the inspection numeral A1, the second inspection data of the first equipment includes the inspection numeral A2, the third inspection data of the first equipment includes the inspection numeral A3, the first differential data of the first equipment includes the differential numeral ΔA1 , the second differential data of the first equipment includes the differential numeral ΔA2, the first inspection data of the second equipment includes the inspection numeral B1, the second inspection data of the second equipment includes the inspection numeral B2, the third inspection data of the second equipment includes the inspection numeral B3, the first differential data of the second equipment includes the differential numeral ΔB1, the second differential data of the second equipment includes the differential numeral ΔB2, and the third differential data of the second equipment may include various differentials and/or relational expressions calculated between the A1, A2, A3 and B3 as follows:

ΔB3=B3−A3 (14)

ΔB3=B3−(ΔA3+A2) (15)

ΔB3+ΔA3=B3−A2 (16)

ΔB3+ΔA3=B3−(ΔA2+A1) (17)

ΔB3+ΔA3+ΔA2=B3−A1 (18)

Further, various differentials and/or relational expressions may be further calculated and/or included.

Referring again to FIG. 4A, calibrating the configuration of the second equipment with reference to the third differential data of the second equipment (step SB34) may be further included. Next, the first period of operation PB1, the second period of operation PB2 and/or a fourth period of operation PB4 of the second equipment may be performed.

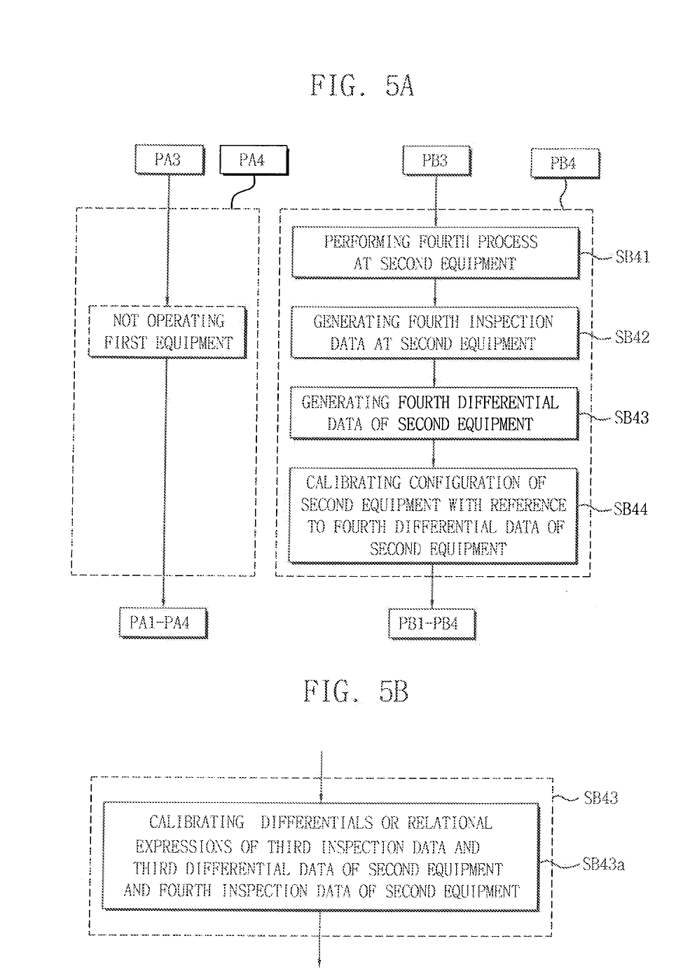

FIGS. 5A and 5B are flowcharts illustrating a method of fabricating a semiconductor device in accordance with a fourth exemplary embodiment of the present general inventive concept.

Referring to FIG. 5A, the method of fabricating a semiconductor device in accordance with the fourth exemplary embodiment of the present general inventive concept may include any one and/or two or more of the methods of fabricating a semiconductor device in accordance with the first to third embodiments, and a fourth period of operations PA4 and PB4 may be performed at the first equipment and the second equipment, respectively. The fourth period of operation PA4 of the first equipment may include stopping the operation of the first equipment. For example, the fourth period may be a fourth day.

The fourth period of operation PB4 of the second equipment may include performing a fourth process at the second equipment (step SB41), generating fourth inspection data of the second equipment (step SB42), and generating fourth differential data of the second equipment (step SB43). The fourth process of the second equipment may include the same process as the first to third processes of the second equipment. For example, the fourth period of operation PB4 of the second equipment may include forming a seventh pattern on a seventh wafer. The seventh pattern may have the same features as the sixth pattern.

Referring to FIG. 5B, generating the fourth differential data of the second equipment (step SB43) may include calculating differentials and/or relational expressions of the third inspection data and the third differential data of the second equipment, and the fourth inspection data of the second equipment. For example, generating the fourth differential data of the second equipment (step SB43) may include comparing inspection/measurement results of the sixth pattern formed on the sixth wafer and inspection/measurement results of the seventh pattern formed on the seventh wafer. When the fourth inspection data of the second equipment includes the inspection numeral B4, the fourth differential data of the second equipment may include various differentials and/or relational expressions calculated between the A1, A2, A3, B3 and B4 as follows:

ΔB4=B4−B3 (19)

ΔB4=B4−(ΔB3+ΔA3+ΔA2+A1) (20)

B4=ΔB4+ΔB3+ΔA3+ΔA2+A1 (21)

ΔB4+ΔB3+ΔA3+ΔA2=B4−A1 (22)

Furthermore, various differentials and/or relational expressions may be further calculated and/or included.

Referring again to FIG. 5A, the fourth period of operation PB4 of the second equipment may further include calibrating the configuration of the second equipment with reference to the fourth differential data of the second equipment (step SB44). Next, one of the first to fourth periods of operations PA1 to PA4 and/or PB1 to PB4 of the first equipment and/or the second equipment may be performed. That is, the initial configurations of the first equipment and the second equipment may be reset, the first equipment may be operated again, and/or only the second equipment may be operated to perform the next processes.

According to the second to fourth embodiments of the inventive concept, since the configurations of the first equipment and the second equipment may be calibrated with reference to the initial configuration of the first equipment, the process, the process results and environments of the equipment may be controlled and maintained always within a certain range.

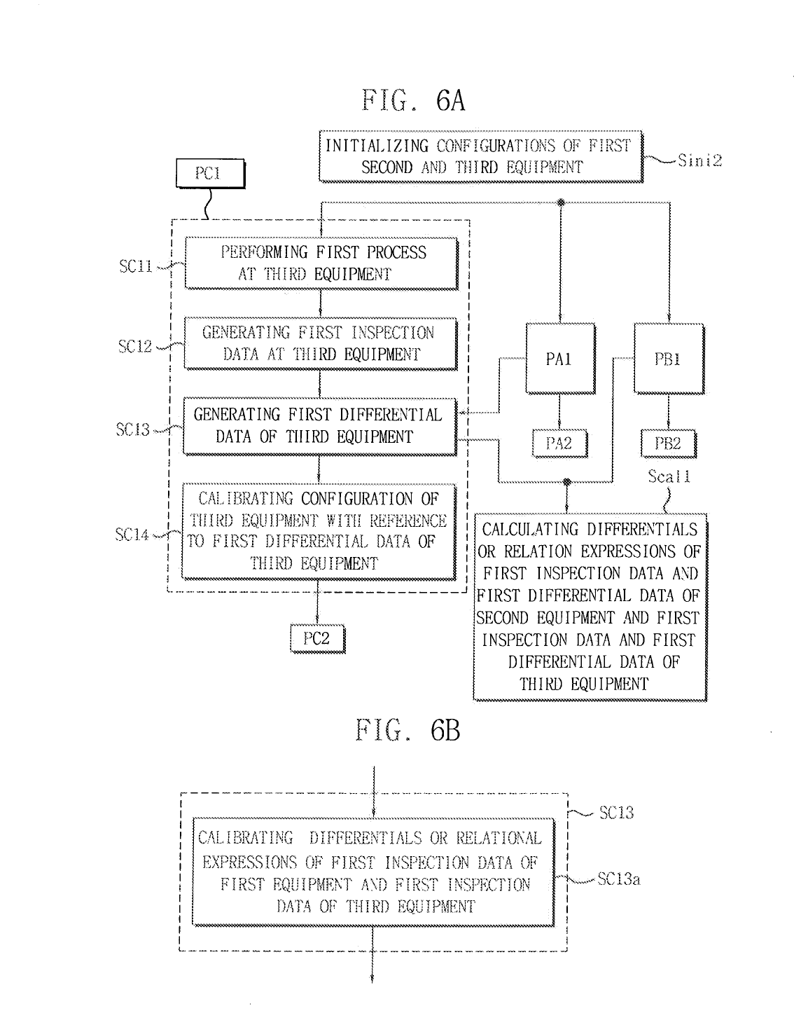

FIGS. 6A and 6B are flowcharts illustrating a method of fabricating a semiconductor device in accordance with a fifth exemplary embodiment of the present general inventive concept.

Referring to FIG. 6A, the method of fabricating a semiconductor device in accordance with the fifth exemplary embodiment of the present general inventive concept may include initializing configurations of the first equipment, the second equipment, and the third equipment (step Sini2). The embodiment may include three or more equipment.

Next, a first period of operations PA1, PB1 and PC1 may be independently performed at the first equipment, the second equipment and the third equipment, respectively. For example, performing the first period of operation PA1 at the first equipment may include forming first patterns on a plurality of first wafers and inspecting/measuring the first patterns formed on first to third ones of the first wafers.

Performing the first period of operation PB1 at the second equipment may include forming a second pattern on a second wafer, inspecting/measuring the second pattern formed on the second wafer, and comparing inspection/measurement results of the first pattern formed on the second one of the first wafers and inspection/measurement results of the second pattern formed on the second wafer. The second pattern may have the same features as the first patterns.

The first period of operation PC1 of the third equipment may include performing a first process at the third equipment (step SC11), generating first inspection data of the third equipment (step SC12), and generating first differential data of the third equipment (step SC13).

The first process of the third equipment may include the same process as the first process of the first equipment and/or the second equipment. For example, the first process of the third equipment may include forming a third pattern on third wafer, and inspecting/measuring the third pattern formed on the third wafer. The third pattern may have the same features as the first patterns.

Referring further to FIG. 6B, generating the first differential data of the third equipment (step SC13) may include calculating differentials and/or relational expressions of the first inspection data of the first equipment and the first inspection data of the third equipment (step SC13a). For example, generating the first differential data of the third equipment (step SC13) may include comparing inspection/measurement results of the first pattern formed on third one of the first wafers and inspection/measurement results of the third pattern formed on the third wafer. When the first inspection data of the first equipment includes the inspection numeral A1 and the first inspection data of the third equipment includes the inspection numeral C1, the first differential data of the third equipment may include differentials and/or relational expressions calculated between the A1 and C1 as follows:

ΔC1=C1−A1 (23)

Referring again to FIG. 6A, the first period of operation PC1 of the third equipment may further include calibrating the configuration of the third equipment with reference to the first differential data of the third equipment (step SC14). Next, a second period of operation PC2 of the third equipment may be performed.

In addition, the method of fabricating the semiconductor device in accordance with the fifth exemplary embodiment of the present general inventive concept may further include calculating differentials and/or relational expressions of the first inspection data and the first differential data of the second equipment, and the first inspection data and the first differential data of the third equipment. For example, various differentials and/or relational expressions calculated between the B1 and C1 may be as follows:

B1−ΔB1=C1−ΔC1 (24)

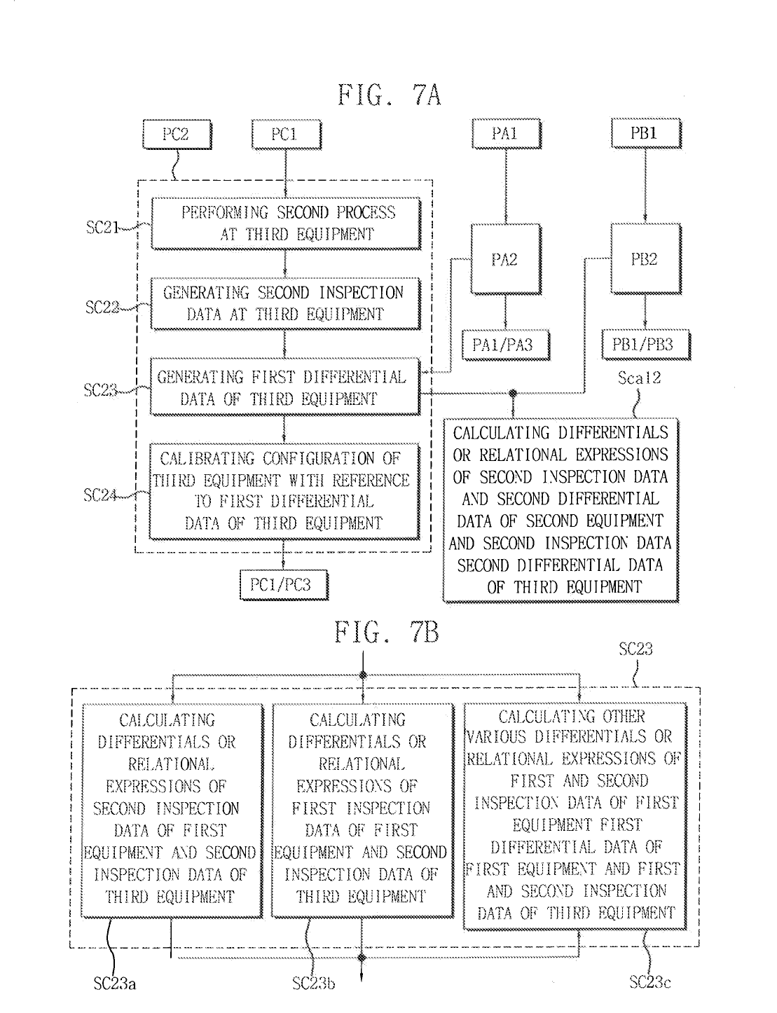

FIGS. 7A and 7B are flowcharts illustrating a method of fabricating a semiconductor device in accordance with a sixth exemplary embodiment of the present general inventive concept.

Referring to FIG. 7A, the method of fabricating a semiconductor device in accordance with the sixth exemplary embodiment of the present general inventive concept may include the method of fabricating the semiconductor device in accordance with the fifth exemplary embodiment, and independently performing the second period of operations PA2, PB2 and PC2 at the first equipment, the second equipment and the third equipment, respectively.

For example, performing the second period of operations PA2 at the first equipment may include forming fourth patterns on a plurality of fourth wafers, inspecting/measuring the fourth pattern formed on first to third ones of the fourth wafers, and comparing inspection/measurement results of the first pattern on the first to third ones of the first wafers and inspection/measurement results of the fourth pattern on a first one of the fourth wafers. The fourth pattern may have the same features as the first patterns.

For example, performing the second period of operations PB2 at the second equipment forming a fifth pattern on a fifth wafer, inspecting/measuring the fifth pattern formed on the fifth wafer, and comparing inspection/measurement results of the fourth pattern on the second one of the fourth wafers and results of inspection/measurement of the fifth pattern on the fifth wafer. The fifth pattern may have the same features as the fourth patterns.

The second period of operation PC2 of the third equipment may include performing a second process at the third equipment (step SC21), generating second inspection data of the third equipment (step SC22), and generating first differential data of the third equipment (step SC23).

The second process of the third equipment may include the same process as the second process of the first equipment and/or the second equipment. For example, the second process of the third equipment may include forming a sixth pattern on a sixth wafer. The sixth wafer may have the same features as the fourth patterns.

Generating the second inspection data of the third equipment (step SC22) may include inspecting/measuring results of the second process performed by the third equipment. For example, generating the second inspection data of the third equipment (step SC22) may include inspecting/measuring the sixth pattern formed on the sixth wafer.

Referring further to FIG. 7B, generating the second differential data of the third equipment (step SC23) may include calculating differentials and/or relational expressions of the second inspection data of the first equipment and the second inspection data of the third equipment (step SC23a). For example, generating the second differential data of the third equipment (step SC23) may include comparing inspection/measurement results of the fourth pattern formed on the third one of the fourth wafers and inspection/measurement results of the sixth pattern formed on the sixth wafer. Generating the second differential data of the third equipment (step SC23) may further include calculating differentials and/or relational expressions of the first inspection data of the first equipment and the second inspection data of the second equipment (step SC23b), and calculating various differentials and/or relational expressions of the first and second inspection data of the first equipment, the first differential data of the first equipment, and the first and second inspection data of the third equipment (step SC23c).

For example, when the first inspection data of the first equipment includes the inspection numeral A1, the second inspection data of the first equipment includes the inspection numeral A2, the first differential data of the first equipment includes the differential numeral ΔA1, the first inspection data of the third equipment includes the inspection numeral C1, the second inspection data of the third equipment includes the inspection numeral C2, and the second differential data of the third equipment may include various differentials and/or relational expressions calculated between the A1, A2 and C2 as follows:

ΔC2=C2−A2 (25)

ΔC2=C2−(ΔA2+A1) (26)

ΔC2+ΔA2=C2−A1 (27)

In addition, various differentials and/or relational expressions may be further calculated and/or included.

Referring again to FIG. 7A, calibrating configuration of the third equipment with reference to the second differential data of the third equipment (step SC24) may be further included. Next, the first period of operation PC1 and/or a third period of operation PC3 of the third equipment may be performed.

In addition, the method of fabricating a semiconductor device in accordance with the sixth exemplary embodiment of the present general inventive concept may further include calculating differentials and/or relational expressions of the second inspection data and the second differential data of the second equipment, and the second inspection data and the second differential data of the third equipment (step Scal2). For example, differentials and/or relational expressions calculated between the B2 and C2 may be as follows:

B2−ΔB2=C2−ΔC2 (28)

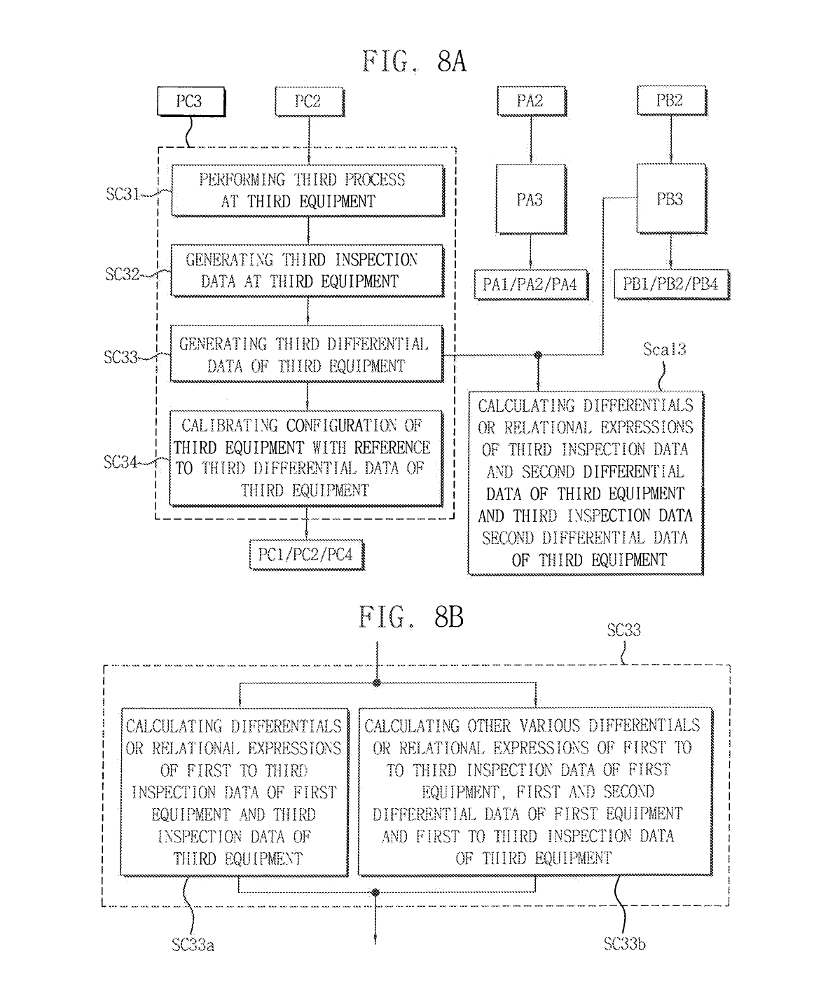

FIGS. 8A and 8B are flowcharts illustrating a method of fabricating a semiconductor device in accordance with a seventh exemplary embodiment of the present general inventive concept.

Referring to FIG. 8A, the method of fabricating a semiconductor device in accordance with a seventh exemplary embodiment of the present general inventive concept may include the methods of fabricating a semiconductor device in accordance with the fifth and sixth exemplary embodiments, and a third period of operations PA3, PB3 and PC3 may be independently performed at the first equipment, the second equipment and the third equipment, respectively.

For example, performing the third period operation (PA3) at the first equipment may include forming seventh patterns on a plurality of seventh wafers, inspecting/measuring the seventh pattern formed on first to third ones of the seventh wafers, and/or comparing inspection/measurement results of the seventh pattern formed on the first one of the fourth wafers and inspection/measurement results of the seventh pattern formed on the first one of the seventh wafers.

For example, performing the third period operation (PB3) at the second equipment may include forming an eighth pattern on an eighth wafer, inspecting/measuring the eighth pattern formed on the eighth wafer, and/or comparing inspection/measurement results of the seventh pattern formed on the second one of the seventh wafers and inspection/measurement results of the eighth pattern formed on the eighth wafer.

The third period of operation PC3 of the third equipment may include performing a third process at the third equipment (step SC31), generating the third inspection data of the third equipment (step SC32), and generating the third differential data of the third equipment (step SC33).

The third process of the third equipment may include the same process as the third process of the first equipment and/or the second equipment. For example, the third process of the third equipment may include forming a ninth pattern on a ninth wafer. The ninth pattern may have the same features as the seventh patterns formed on the seventh wafers.

Generating the third inspection data of the third equipment (step SC32) may include inspecting/measuring results of the third process performed by the third equipment. For example, generating the third inspection data of the third equipment (step SC32) may include inspecting/measuring the ninth pattern formed on the ninth wafer.

Referring further to FIG. 8B, generating the third differential data of the third equipment (step SC33) may include calculating differentials and/or relational expressions of the first to third inspection data of the first equipment, and the third inspection data of the third equipment (step SC33a). For example, generating the third differential data of the third equipment (step SC33) may include comparing inspection/measurement results of the seventh pattern formed on the third one of the seventh wafers and inspection/measurement results of the ninth pattern formed on the ninth wafer. Generating the third differential data of the third equipment (step SC33) may further include calculating other various differentials and/or relational expressions of the first to third inspection data of the first equipment, the first and second differential data of the first equipment, and the first to third inspection data of the third equipment (step SC33b).

For example, when the first inspection data of the first equipment includes the inspection numeral A1, the second inspection data of the first equipment includes the inspection numeral A2, the third inspection data of the first equipment includes the inspection numeral A3, the first differential data of the first equipment includes the differential numeral ΔA1, the second differential data of the first equipment includes the differential numeral ΔA2, the first inspection data of the third equipment includes the inspection numeral C1, the second inspection data of the third equipment includes the inspection numeral C2, the third inspection data of the third equipment includes the inspection numeral C3, the first differential data of the third equipment includes the differential numeral ΔC1, the second differential data of the third equipment includes the differential numeral ΔC2, and the third differential data of the third equipment may include various differentials and/or relational expressions calculated between the A1, A2, A3 and C3 as follows:

ΔC3=C3−A3 (29)

ΔC3=C3−(ΔA3+A2) (30)

ΔC3+ΔA3=C3−A2 (31)

ΔC3+ΔA3=C3−(ΔA2+A1) (32)

ΔC3+ΔA3+ΔA2=C3−A1 (33)

Further, various differentials and/or relational expressions may be further calculated and/or included.

Referring again to FIG. 8A, calibrating the configuration of the third equipment with reference to the third differential data of the third equipment (step SC34) may be further included. Next, the first period of operation PC1, the second period of operation PC2 and/or a fourth period of operation PC4 of the third equipment may be performed.

In addition, the method of fabricating a semiconductor device in accordance with the fifth embodiment of the inventive concept may further include calculating differentials and/or relational expressions of the third inspection data and the third differential data of the second equipment, and the third inspection data and the third differential data of the third equipment (step Scal3). For example, differentials and/or relational expressions calculated between the B3 and C3 may be included as follows:

B3−ΔB3=C3−ΔC3 (34)

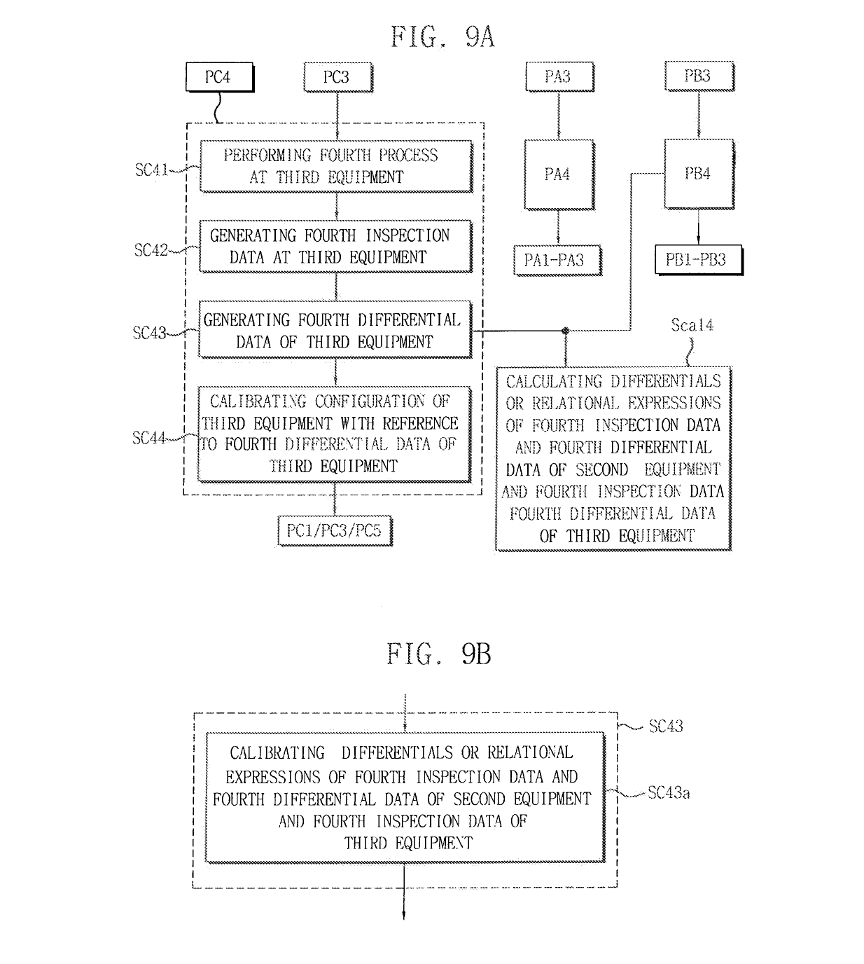

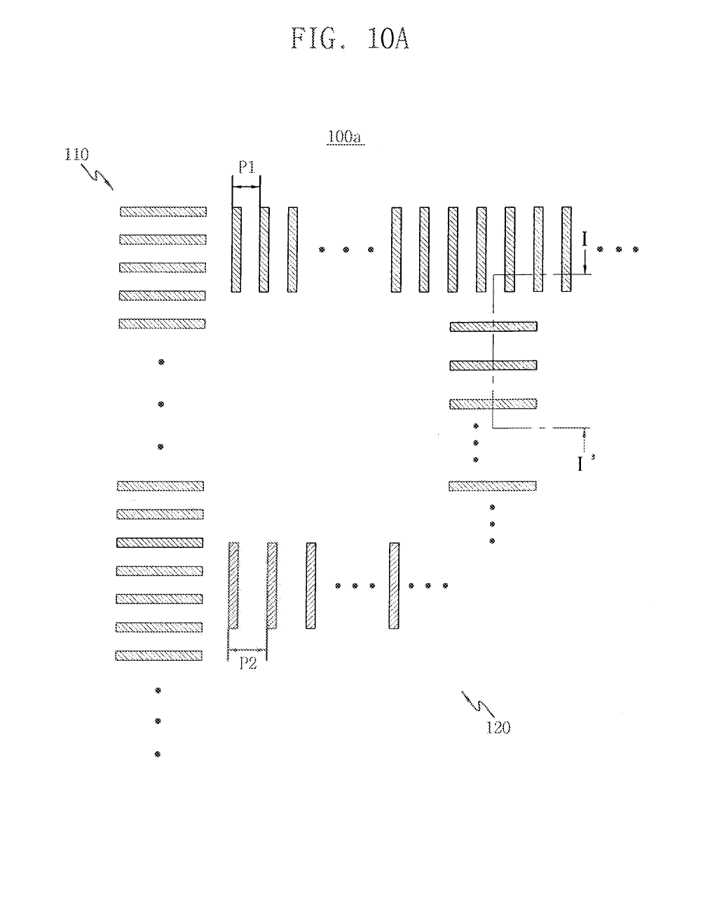

FIGS. 9A and 9B are flowcharts illustrating a method of fabricating a semiconductor device in accordance with an eighth exemplary embodiment of the present general inventive concept.

Referring to FIG. 9A, the method of fabricating a semiconductor device in accordance with the eighth exemplary embodiment of the present general inventive concept may include at least any one and/or two or more of the methods of fabricating a semiconductor device in accordance with the fifth to seventh exemplary embodiments, and a fourth period of operations PA4, PB4 and PC4 may be performed at the first to third equipment, respectively.

For example, performing the fourth period of operation PA4 at the first equipment may include stopping the operation of the first equipment.

The fourth period of operation PB4 at the second equipment may include forming tenth patterns on a plurality of tenth wafers, generating fourth inspection data by inspecting/measuring the tenth pattern formed on first to second ones of the tenth wafers, and comparing inspection/measurement results of the eighth pattern formed on the eighth wafer and inspection/measurement results of the tenth pattern formed on the first one of the tenth wafers.

The fourth period of operation PC4 of the third equipment may include performing a fourth process at the third equipment (step SC41), generating fourth inspection data of the third equipment (step SC42), and generating fourth differential data of the third equipment (step SC43). For example, performing a fourth process at the third equipment (step SC41) may include forming an eleventh pattern on an eleventh wafer. The eleventh pattern may have the same features as the tenth patterns. Generating fourth inspection data of the third equipment (step SC42) may include inspecting/measuring the eleventh pattern formed on the eleventh wafer.

Referring to FIG. 9B, generating the fourth differential data (step SC43) may include calculating differentials and/or relational expressions of the third inspection data and the third differential data of the third equipment, and the fourth inspection data of the third equipment (step SC43a). For example, generating the fourth differential data (step SC43) of the third equipment may include comparing inspection/measurement results of the tenth pattern formed on the second one of the tenth wafers and inspection/measurement results of the eleventh pattern formed on the eleventh wafer. When the fourth inspection data of the third equipment includes the inspection numeral C4, the fourth differential data of the third equipment may include various differentials and/or relational expressions calculated between the A1, A2, A3 and C4 as follows:

ΔC4=C4−C3 (35)

ΔC4=C4−(ΔC3+ΔA3+ΔA2+A1) (36)

C4=ΔC4+ΔC3+ΔA3+ΔA2+A1 (37)

ΔC4+ΔC3+ΔA3+ΔA2=C4−A1 (38)

Further, various differentials and/or relational expressions may be further calculated and/or included.

Referring again to FIG. 9A, the fourth period of operation PC4 of the third equipment may further include calibrating the configuration of the third equipment with reference to the fourth inspection data of the third equipment (step SC44). Next, any one of the first to third and/or fifth period of operations PC1 to PC3 and PC5 of the third equipment may be performed. That is, the initial configurations of the first to third equipment may be reset, the first equipment may be operated again, and/or all of the equipment may be operated to perform the following processes.

In addition, the method of fabricating a semiconductor device in accordance with the eighth embodiment of the inventive concept may further include calculating differentials and/or relational expressions of the fourth inspection data and the fourth differential data of the second equipment, and the fourth inspection data and the fourth differential data of the third equipment (step Scal4). For example, various differentials and/or relational expressions calculated between the B4 and C4 may be as follows:

ΔC4=C4−B4 (39)

ΔC4=C4−(ΔB4+ΔB3+ΔA3+ΔA2+A1) (40)

ΔC4+ΔB4+ΔB3+ΔA3+ΔA2=C4−A1 (41)

In addition, various differentials and/or relational expressions may be further calculated and/or included.

According to the fifth to eighth exemplary embodiments of the present general inventive concept, since the configurations of the first to third equipment may be calibrated with reference to the initial configuration of the first equipment, the process, process results and environments of the equipment may always be controlled and maintained within a certain range.

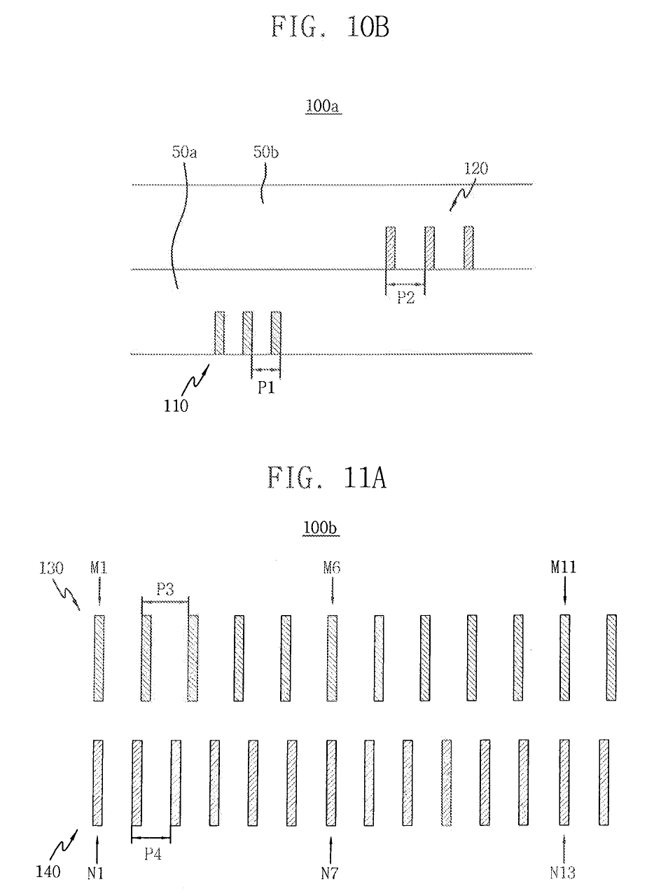

FIGS. 10A to 12 are views showing the exemplary embodiments to which the methods of fabricating a semiconductor device in accordance with the present general inventive concept are applied. In order to exemplarily explain examples to which the methods of fabricating a semiconductor device in accordance with the present general inventive concept are more complicatedly applied, the case applied to the photolithography process and photolithography equipment will be described. In particular, the case to inspect precision of the overlay of the photolithography will be described. Precision of the overlay means how precisely patterns formed by two sheets of photo masks and/or reticles are aligned in a vertical direction.

FIG. 10A is a plan view schematically showing an overlay monitoring pattern, and FIG. 10B is a simplified longitudinal cross-sectional view in I-I′ direction of the overlay monitoring pattern.

Referring to FIG. 10A, an overlay monitoring pattern 100a may include a first pattern 110 and a second pattern 120, which are arranged parallel and/or perpendicular to each other. Each of the first pattern 110 and the second pattern 120 may include a plurality of parallel bars. The first pattern 110 may be disposed at an outer periphery, and the second pattern 120 may be disposed inside the first pattern 110. The bars may be arranged in parallel in a vertical or horizontal direction. The first pattern 110 may be arranged at a first pitch P1, and the second pattern may be arranged at a second pitch P2. The first pitch P1 may be smaller than the second pitch P2. However, in an applied exemplary embodiment, the first pitch P1 may be equal to the second pitch P2. The first pattern 110 may be formed by a first photolithography process, and the second pattern 120 may be formed by a second photolithography process. For example, the first pattern 110 may be formed through a front period of process, and the second pattern 120 may be formed through a rear period of process.

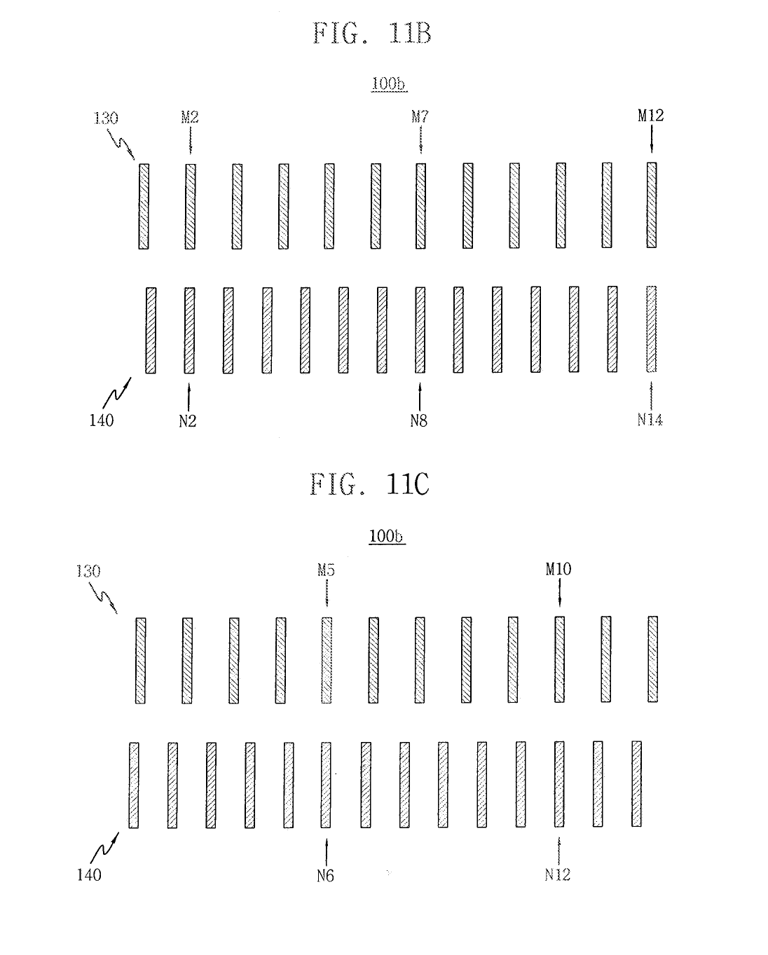

Referring to FIG. 10B, the first pattern 110 may be formed at a lower layer 50a, and the second pattern 120 may be formed at an upper layer 50b. In the inventive concept, the inspection processes may include inspecting/measuring a degree of alignment of the first pattern 110 and the second pattern 120. The inspection processes may include inspecting/measuring a relative positional relationship and/or the distance of the first pattern 110 and the second pattern 120. More specifically, the degree of alignment may be numerically represented by calculating the distance to a position, at which another specific portion of the first pattern 110 and the second pattern 120 is located, with reference to a specific portion of the first pattern 110 and/or a specific portion of the second pattern 120. Such concept will be described in detail with reference to FIGS. 11A to 110.

FIGS. 11A to 11C are plan views schematically showing overlay monitoring patterns, FIG. 11A showing a case in which an overlay differential is 0 (zero), FIG. 11B showing a case in which an overlay differential is positive (+), and FIG. 11C showing a case in which an overlay differential is negative (−). Referring to FIGS. 11A to 11C, the overlay monitoring pattern 100b may include a third pattern 130 and a fourth pattern 140, each including a plurality of bar patterns arranged in parallel in a horizontal direction. The third pattern 130 may be arranged at a third pitch P3, and the fourth pattern 140 may be arranged at a fourth pitch. While the third pattern 130 and the fourth pattern 140 are different from the first pattern 110 and the second pattern 120, it will be understood that technical spirits thereof are similar to each other.

The inspection data and/or inspection process performed using the overlay monitoring pattern 100b may be collected as follows: the bars at left end portions of the third pattern 130 and the fourth pattern 140 may be set as reference points and/or a reference line. When the reference points are positioned on the same horizontal coordinates, M1, M6 and M11 bars of the third patterns 130 will be arranged on the same horizontal coordinates.

Referring to FIG. 11B, when the overlay differential is positive (+), the fourth pattern 140 may be moved and formed relatively rightward more than the third pattern 130. If M2 and N2, M7 and N8, and M12 and N14 are arranged on the same horizontal coordinates, it may be assumed that the overlay differential is +1. Referring to FIG. 11C, when the overlay differential is positive (−), the fourth pattern 140 may be moved and formed relatively leftward more than the third pattern 130. If M5 and N6, and M10 and N12 are arranged on the same horizontal coordinates, it may be assumed that the overlay differential is −1. The third pitch P3 and the fourth pitch P3 may be very variously and finely set. The overlay can be precisely measured, with increased precision depending on the fineness. Each overlay differential may mean a predetermined numeral. That is, the overlay differential ±1 means that the overlay is offset to about ±16 nm. Of course, the overlay differential may be more variously supposed and interpreted.

Referring again to FIGS. 11A to 11C, there is no need to dispose the bars on the same horizontal coordinates. That is, while relative horizontal coordinates of the bar of the third pattern 130 and the bar of the fourth pattern 140 are measured, each horizontal coordinate may be independently measured to monitor the overlay. However, in order to easily explain the inventive concept, it has been merely assumed that the specific bars are positioned on the same horizontal coordinates.

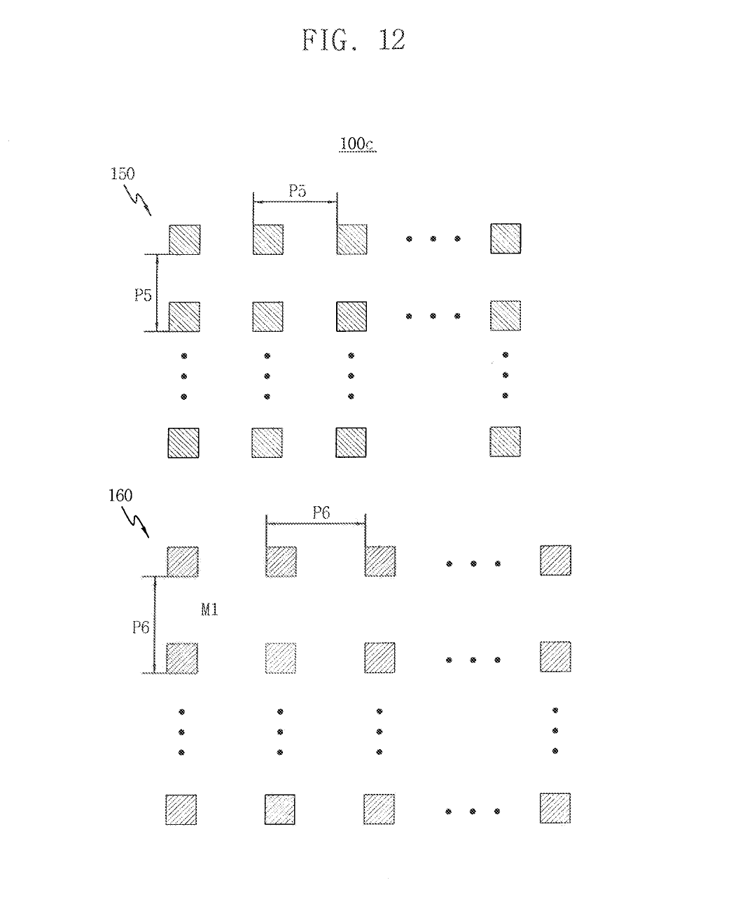

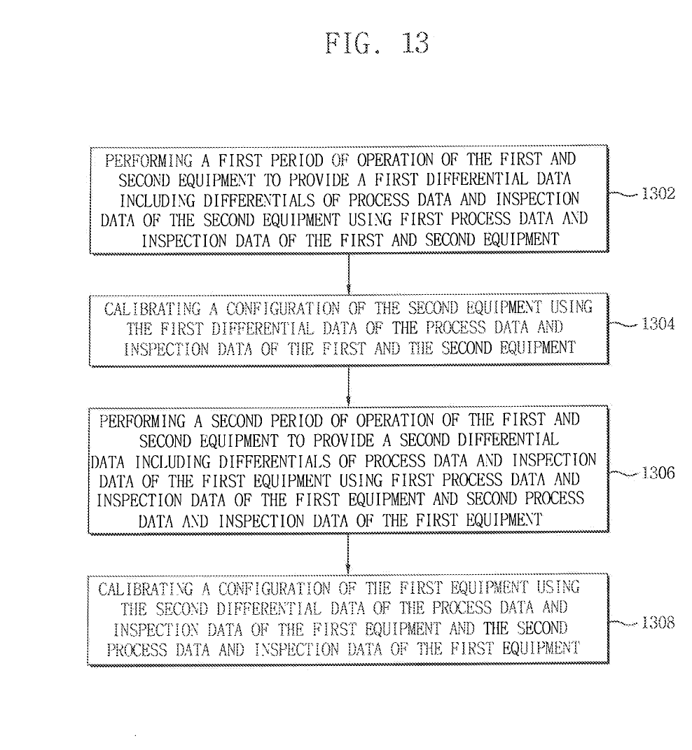

FIG. 12 is a plan view illustrating another shape in which overlay monitoring patterns may simultaneously measure horizontal coordinates and/or vertical coordinates. Referring to FIG. 12, another overlay monitoring pattern 100c may include a fifth pattern 150 and a sixth pattern 160 including a plurality of islands arranged in a horizontal direction and a vertical direction. An inspection method may be understood with reference to FIGS. 11A and 11B.

Referring again to FIGS. 10A to 12, in various embodiments of the inventive concept, the inspection data may include, for example, overlay numerals. That is, according to the inventive concept, overlay differentials of a plurality of photolithography equipment may be periodically measured and calibrated. As described above, differentials of the respective processes and/or equipment of an etching process, a deposition process, a planarization process, an ion plantation process, a cleaning process, and/or other various processes, as well as overlays of photolithography equipment, may be periodically measured and calibrated. The overlay inspection method in accordance with the inventive concept may be understood by applying a theory of vernier calipers.

Otherwise, names and functions of components, which are not indicated by reference numerals or to which only reference numerals are marked, will be easily understood from other drawings and descriptions thereof of the specification.

As may be seen from the foregoing, according to a monitoring method and/or a calibration method of the process and/or equipment accordance with various exemplary embodiments of the inventive concept, process ability and process results of the equipment may be monitored to obtain numerically various differentials and/or relational expressions showing relationship thereof. In particular, data of the process ability and process results of the plurality of equipment compared with the process ability and process results of the initial reference equipment may be obtained. Accordingly, since the plurality of equipment may be always measured, calculated and calibrated with reference to the initial configuration of the reference equipment, the process, process results and environments of the equipment may always be controlled and maintained within a certain range. In particular, when the present general inventive concept is applied to the photolithography process, since the processes and equipment may be monitored and calibrated in an after develop inspection (ADI) process, the processes and equipment may be rapidly stabilized.

As illustrated in FIG. 13, in another exemplary embodiment, the method of fabricating a semiconductor device at first equipment and second equipment, a semiconductor includes performing a first period of operation to provide a first differential data including differentials of process and inspection data of the second equipment using first process and inspection data from the first and second equipment (1302); calibrating a configuration of the second equipment using the first differential data of the process and inspection data of the first and the second equipment (1304); performing a second period of operation to provide a second differential data including differentials of process and inspection data of the first equipment using first process and inspection data from the first equipment and second process and inspection data from the first equipment (1306); and calibrating a configuration of the first equipment using the second differential data of the process and inspection data from the first equipment and the second process and inspection data from the first equipment (1308).

Although a few exemplary embodiments of the present general inventive concept have been shown and described, it will be appreciated by those skilled in the art that changes may be made in these exemplary embodiments without departing from the principles and spirit of the general inventive concept, the scope of which is defined in the appended claims and their equivalents.

What is claimed is:

1. A method of fabricating a semiconductor device, comprising:
performing a first period of operation and a second period of operation at first equipment and second equipment,
wherein the first period of operation comprises:
performing a first patterning process at each of the first equipment and the second equipment;
generating first inspection data of the first equipment, and first inspection data of the second equipment;
generating first differential data of the second equipment comprising differentials of the first inspection data of the first equipment and the first inspection data of the second equipment; and
calibrating a configuration of the second equipment with reference to the first differential data of the second equipment, and the second period of operation comprises:
performing a second patterning process at the first equipment;
generating second inspection data of the first equipment;
generating first differential data of the first equipment comprising differentials of the first inspection data of the first equipment and the second inspection data of the first equipment; and
calibrating a configuration of the first equipment with reference to the first differential data of the first equipment.

2. The method according to claim 1, wherein the patterning process comprises forming a photoresist pattern.

3. The method according to claim 1, wherein the at least one of the first equipment and the second equipment comprises photolithography equipment.

4. The method according to claim 1, wherein the second period of operation further includes:
performing a second patterning process at the second equipment;
generating second inspection data of the second equipment;
generating second differential data of the second equipment including differentials of the second inspection data of the first equipment and the second inspection data of the second equipment; and
calibrating the configuration of the second equipment with reference to the second differential data of the second equipment.

5. The method according to claim 4, further comprising performing a third period of operation at the first equipment and the second equipment,
wherein the third period of operation includes:
performing a third patterning process at the first equipment;
generating third inspection data of the first equipment;
generating second differential data of the first equipment including differentials of the second inspection data of the first equipment and the third inspection data of the first equipment; and
calibrating the configuration of the first equipment with reference to the second differential data of the first equipment.

6. The method according to claim 5, wherein the third period of operation further includes:
performing a third patterning process at the second equipment;
generating third inspection data of the second equipment;
generating third differential data of the second equipment including differentials of the third inspection data of the first equipment and the third inspection data of the second equipment; and
calibrating the configuration of the second equipment with reference to the third differential data of the second equipment.

7. The method according to claim 6, further comprising performing a fourth period of operation at the first equipment and the second equipment,
wherein the fourth period of operation comprises:
performing a fourth patterning process at the second equipment;
generating fourth inspection data of the second equipment;
generating fourth differential data of the second equipment including differentials of the third inspection data of the second equipment and the fourth inspection data of the second equipment; and
calibrating the configuration of the second equipment with reference to the fourth differential data of the second equipment.

8. A method of fabricating a semiconductor device comprising:
performing a first process of a first period at a first equipment, wherein the first process of the first period comprises forming first patterns on first to third ones of first wafers;
performing a second process of the first period at a second equipment, wherein the second process of the first period comprises forming a second pattern on a second wafer and generating a first differential data of the second equipment by comparing inspection results of the first pattern on the second one of the first wafer and inspection results of the second pattern on the second wafer; and
performing a third process of the first period at a third equipment, wherein the third process of the first period comprises forming a third pattern on a third wafer and generating a first differential data of the third equipment by comparing inspection result of the first pattern on the third one of the first wafer and inspection results of the third pattern on the third wafer.

9. The method according to claim 8, further comprising:
calibrating a configuration of the second equipment with reference to the first differential data of the second equipment, and
calibrating a configuration of the third equipment with reference to the first differential data of the third equipment.

10. The method according to claim 8, further comprising:
performing a first process of a second period at the first equipment, wherein the first process of the second period comprises forming fourth patterns on first to third ones of fourth wafers, and generating a first differential data of the first equipment by comparing inspection results of the first pattern on the first one of the first wafers and the fourth pattern on the first one of the fourth wafers;
performing a second process of the second period at the second equipment, wherein the second process of the second period comprises forming a fifth pattern on a fifth wafer, and generating a second differential data of the second equipment by comparing inspection results of the fourth pattern on the second one of the fourth wafers and inspection results of the fifth pattern on the fifth wafer; and
performing a third process of the second period at the third equipment, wherein the third process of the second period comprises forming a sixth pattern on a sixth wafer, and generating a second differential data of the third equipment by comparing inspection results of the fourth pattern on the third one of the fourth wafers and inspection results of the sixth pattern on the sixth wafer.

11. The method according to claim 10, further comprising:
calibrating a configuration of the first equipment with reference to the first differential data of the first equipment;
calibrating a configuration of the second equipment with reference to the second differential data of the second equipment; and
calibrating a configuration of the third equipment with reference to the second differential data of the third equipment.

12. The method according to claim 10, further comprising:
performing a first process of a third period at the first equipment, wherein the first process of the third period comprises forming seventh patterns on first to third ones of seventh wafers and generating a second differential data of the first equipment by comparing inspection results of the fourth pattern on the first one of the fourth wafers and the seventh pattern on the first one of the seventh wafers;
performing a second process of the third period at the second equipment, wherein the second process of the third period comprises forming an eighth pattern on a eighth wafer, and generating a third differential data of the second equipment by comparing inspection results of the seventh pattern on the second one of the seventh wafers and inspection results of the eighth pattern on the eighth wafer; and
performing a third process of the third period at the third equipment, wherein the third process of the third period comprises forming a ninth pattern on a ninth wafer, and generating a third differential data of the third equipment by comparing inspection results of the seventh pattern on the third one of the seventh wafers and inspection results of the ninth pattern on the ninth wafer.

13. The method according to claim 12, further comprising:
performing a first process of a fourth period at the second equipment, wherein the first process of the fourth period comprises forming tenth patterns on first and second ones of tenth wafers and generating a fourth differential data of the second equipment by comparing inspection results of the eighth pattern on the eighth wafer and inspection results of the tenth pattern on the first one of tenth wafers; and
performing a second process of the fourth period at the third equipment, wherein the second process of the fourth period comprises forming an eleventh pattern on an eleventh wafer, and generating a fourth differential data of the third equipment by comparing inspection results of the tenth pattern on the second one of the tenth wafers and inspection results of the eleventh pattern on the eleventh wafer.

14. The method according to claim 14, further comprising stopping operation of the first equipment in the fourth period.

15. The method according to claim 8, wherein the first patterns, the second pattern, and the third pattern have the same features.

16. A method of fabricating a semiconductor device at first equipment and second equipment, the method comprising:
performing a first period of operation of the first and second equipment to provide a first differential data including differentials of process data and inspection data of the second equipment using first process data and inspection data of the first and second equipment;
calibrating a configuration of the second equipment using the first differential data of the process data and inspection data of the first and the second equipment;
performing a second period of operation of the first and second equipment to provide a second differential data including differentials of process data and inspection data of the first equipment using first process data and inspection data of the first equipment and second process data and inspection data of the first equipment; and
calibrating a configuration of the first equipment using the second differential data of the process data and inspection data of the first equipment and the second process data and inspection data of the first equipment.

17. The method according to claim 16, further comprising performing a third period of operation,
wherein the third period of operation includes:
performing a third process at the second equipment;
generating third inspection data of the second equipment;
generating third differential data of the second equipment including differentials of the second inspection data of the second equipment and the third inspection data of the second equipment; and
calibrating the configuration of the second equipment with reference to the third differential data of the second equipment.

18. The method according to claim 16, wherein at least one of the first and second processes is one of: patterning; photolithography; an exposure process; a development process; and a pre-bake process.

19. The method according to claim 16, wherein the inspection data is one of: geometric positional relationships of photoresist patterns and critical dimensions (CD) of the photoresist patterns

20. The method according to claim 19, wherein inspection data includes data from an after develop inspection process.
